(19) United States
(12) Patent Application Publication
(10) Pub. No.: US 2025/0253197 A1
(43) Pub. Date: Aug. 7, 2025

(54) CHIP PACKAGE STRUCTURE AND MANUFACTURING METHOD THEREOF

(71) Applicant: TONG HSING ELECTRONIC INDUSTRIES, LTD., Taipei City (TW)

(72) Inventors: Yu-Te Hsieh, Taipei City (TW); WEI-CHUNG CHAO, Taipei City (TW); YAN-WEI CHEN, Taipei City (TW); Wei-Ming Lu, Taipei City (TW); ZZU-CHI CHIU, Taipei City (TW); Chen-Kai Hsu, Taipei City (TW)

(21) Appl. No.: 18/743,752

(22) Filed: Jun. 14, 2024

(30) Foreign Application Priority Data
Feb. 1, 2024 (TW) 113103898

(51) Int. Cl. H01L 23/13; H01L 23/00; H01L 23/28; H01L 25/16

(52) U.S. Cl. CPC H01L 23/13; H01L 23/28; H01L 24/16; H01L 24/37; H01L 24/40; H01L 24/73; H01L 25/16; H01L 24/97; H01L 2224/16225; H01L 2224/37147; H01L 2224/40475; H01L 2224/73255; H01L 2924/15153; H01L 2924/19106

(57) ABSTRACT

A chip package structure and a manufacturing method thereof are provided. The chip package structure includes a circuit substrate, a first chip, a second chip, and a conducting carrier. A bottom surface of the circuit substrate has an opening. The first chip is disposed inside the opening and electrically connected to the circuit substrate. The second chip is disposed on a top surface of the circuit substrate. The conducting carrier is disposed on the second chip and electrically connected to the second chip.

### CROSS-REFERENCE TO RELATED PATENT APPLICATION

This application claims the benefit of priority to Taiwan Patent Application No. 113103898, filed on Feb. 1, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip package structure and a manufacturing method thereof, and more particularly to a chip package structure applied to a power module and a manufacturing method thereof.

### BACKGROUND OF THE DISCLOSURE

In the related art, power modules generally include multiple independently packaged electronic components, such as control IC components, drive IC components, power IC components, and other passive components.

These electronic components are soldered together on a mainboard for integration. However, this manner of jointly soldering all of the components to the mainboard can easily increase the layout complexity of circuit routing, such that the sizes of the power modules cannot easily be reduced, and the development time and cost of the power modules are increased.

Therefore, how to overcome the above-mentioned problems through improvements in structural design has become one of the important issues to be addressed in this field.

### SUMMARY OF THE DISCLOSURE

In response to the above-referenced technical inadequacy, the present disclosure provides a chip package structure and a manufacturing method thereof using system in package (SiP) technology, to solve the problems of the layout difficulty in circuit routing to cause the size of the power modules to be constrained because of the multiple electronic components in the related art being soldered to the mainboard.

In order to solve the above-mentioned problems, one of the technical aspects adopted by the present disclosure is to provide a chip package structure, which includes a circuit substrate, a first chip, a second chip, and a conducting carrier. A bottom surface of the circuit substrate has an opening. The first chip is disposed within the opening and electrically connected to the circuit substrate. The second chip is disposed on a top surface of the circuit substrate. The conducting carrier is disposed on the second chip and electrically connected to the second chip.

In order to solve the above-mentioned problems, another one of the technical aspects adopted by the present disclosure is to provide a method of manufacturing a chip package structure, including: providing a circuit substrate and forming an opening on a bottom surface of the circuit substrate, in which the opening has a plurality of first metal pads disposed therein, a top surface of the circuit substrate has a plurality of second metal pads disposed thereon, and the circuit substrate includes a plurality of conductive through holes therein; providing a first chip to be invertedly disposed in the opening, in which the first chip is electrically connected to the plurality of first metal pads; providing a first encapsulant body to fill into the opening and clad the first chip; providing a second chip to be disposed on the top surface of the circuit substrate and electrically connected to the plurality of second metal pads; providing a conducting carrier to be disposed on and electrically connected to the second chip; and providing a second encapsulant body to clad the second chip and the conducting carrier.

Therefore, in the chip package structure and the manufacturing method thereof provided by the present disclosure, by virtue of the first chip being disposed within the opening and electrically connected to the circuit substrate, and the second chip being disposed on the top surface of the circuit substrate and electrically connected to the conducting carrier, different electronic components can be integrated onto a substrate to form a system in package structure. When the chip package structure is soldered to the mainboard, the layout complexity of the circuit routing can be greatly reduced, which is beneficial for reducing the overall size of the power modules, and declining the development time and manufacturing cost of the power modules.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a chip package structure according to a first embodiment of the present disclosure;

FIG. 2 to FIG. 6 are schematic views of steps of a manufacturing method of the chip package structure according to the first embodiment of the present disclosure;

FIG. 7 is a schematic view of a chip package structure according to a second embodiment of the present disclosure;

FIG. 8 is a schematic view of a chip package structure according to a third embodiment of the present disclosure;

FIG. 9 is a schematic view of a chip package structure according to a fourth embodiment of the present disclosure;

FIG. 10 is a schematic view of a chip package structure according to a fifth embodiment of the present disclosure;

FIG. 11 is a schematic view of a chip package structure according to a sixth embodiment of the present disclosure;

FIG. 12 is a schematic view of a chip package structure according to a seventh embodiment of the present disclosure;

FIG. 13 is a schematic view of a chip package structure according to an eighth embodiment of the present disclosure;

FIG. 14 to FIG. 18 are schematic views of steps of a manufacturing method of the chip package structure according to the eighth embodiment of the present disclosure; and

FIG. 19 to FIG. 23 are flowcharts of the manufacturing method of the chip package structure according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

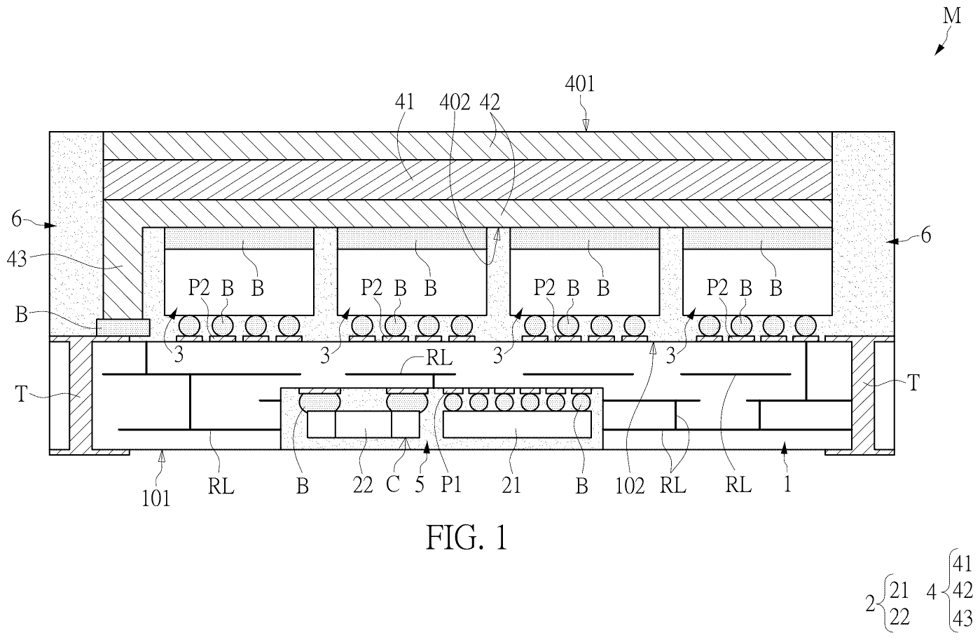

Referring to FIG. 1, a first embodiment of the present disclosure provides a chip package structure M, which includes a circuit substrate 1, a first chip 2, a second chip 3, and a conducting carrier 4. The circuit substrate 1 has a bottom surface 101 and a top surface 102, and the bottom surface 101 has an opening C. The first chip 2 is invertedly disposed within the opening C, and the second chip 3 is disposed on the top surface 102 of the circuit substrate 1. The conducting carrier 4 is disposed on the second chip 3.

For example, the circuit substrate 1 can be a ceramic substrate made of low temperature co-fired ceramics (LTCC), and the conducting carrier can be a direct bonded copper (DBC) substrate, a direct plated copper (DPC) substrate or an active metal brazing (AMB) substrate. The conducting carrier 4 includes a ceramic plate 41 taken as an intermediate layer, and two metal layers 42 that respectively cover a top side and a bottom side of the ceramic plate 41. The two metal layers 42, for example, can be copper foil.

Quantities of the first chip 2 and the second chip 3 are not limited in the present disclosure. For example, the first chip 2 includes an active element 21 such as a drive IC or a control IC. Moreover, the first chip 2 further includes passive elements 22 such as capacitors, inductors, or resistors, or an RLC circuit including these passive elements 22. For example, the second chip 3 can be a power IC such as a metal oxide semiconductor field effect transistor (MOSFET) or an insulated gate bipolar transistor (IGBT). If the second chip 3 is, for example, a MOSFET, a top layer of the second chip 3 includes a drain region, and a bottom layer of the second chip 3 includes a source region and a gate region.

The circuit substrate 1 includes a conductive routing structure RL formed therein by a redistribution layer (RDL) process. The opening C has a plurality of first metal pads P1 disposed therein, and the top surface 102 of the circuit substrate 1 has a plurality of second metal pads P2 disposed thereon. The plurality of first metal pads P1 and the plurality of second metal pads P2 are electrically connected to the conductive routing structure RL. The circuit substrate 1 further includes a plurality of conductive through holes T. The plurality of conductive through holes T are formed inside the circuit substrate 1. The plurality of conductive through holes T penetrate the circuit substrate 1 and is exposed on the bottom surface 101 and the top surface 102. Furthermore, the plurality of first metal pads P1 and the plurality of second metal pads P2 are electrically connected to the conductive through holes T through the conductive routing structure RL.

Reference is further made to FIG. 1. The first chip 2 that is located in the opening C is electrically connected to the plurality of first metal pads P1 through an adhesive member B. The conducting carrier 4 has an upper surface 401 and a lower surface 402. The drain region on the top layer of the second chip 3 is connected to the lower surface 402 of the conducting carrier 4 through the adhesive member B, and the source region and the gate region on the bottom layer of the second chip 3 are connected to the plurality of second metal pads P2 that are located on the top surface 102 of the circuit substrate 1 through the adhesive member B. For example, the adhesive member B can be solder or sintered silver, but the present disclosure is not limited thereto.

The conducting carrier 4 further includes a metal connecting member 43. The metal connecting member 43 is connected to the lower surface 402 of the conducting carrier 4 and located at one side of the second chip 3. The conducting carrier 4 is electrically connected to a part of the conductive through holes T that is exposed from the top surface 102 of the circuit substrate 1 through the metal connecting member 43. In other words, the drain region on the top layer of the second chip 3 is electrically connected to the conductive through holes T through the conducting carrier 4 and the metal connecting member 43.

In the first embodiment, the metal connecting member 43 is formed by extending from the lower metal layer of the conducting carrier 4. That is to say, the metal connecting member 43 is made of copper foil, which is a part extending from the lower copper foil (i.e., the lower metal layer) of the conducting carrier 4.

In addition, the chip package structure M can be soldered to a mainboard (not shown in the figures) through the part of the conductive through holes T that is exposed on the top surface 102 of the circuit substrate 1. Therefore, the first chip 2 and the second chip 3 are electrically connected to other electronic components on the mainboard through the conductive through holes T (not shown in the figures).

Reference is further made to FIG. 1. The chip package structure M further includes a first encapsulant body 5 and a second encapsulant body 6. The first encapsulant body 5 fills into the opening C and clads the first chip 2. The second encapsulant body 6 is disposed on the circuit substrate 1 and clads the second chip 3 and the conducting carrier 4. For example, the first encapsulant body 5 and the second encapsulant body 6 are molding compounds or liquid encapsulants.

It should be noted that the upper surface 401 of the conducting carrier 4 is exposed from the second encapsulant body 6. The conducting carrier 4 can be used not only for electrical conduction but also for heat conduction. Furthermore, the chip package structure M can be used for heat conduction by the exposed upper surface 401 of the conducting carrier 4 contacting an external heat dissipation element (not shown in the figures). The heat conduction between the upper surface 401 and the external heat dissipation element can be further enhanced by a thermal conductive material such as a thermal interface material (TIM) or a silver material. The Carrier 4 can be a ceramic substrate such as an AMB (active metal brazed) substrate, a DBC (direct bonded copper) substrate, or a DPC (direct plated copper) substrate.

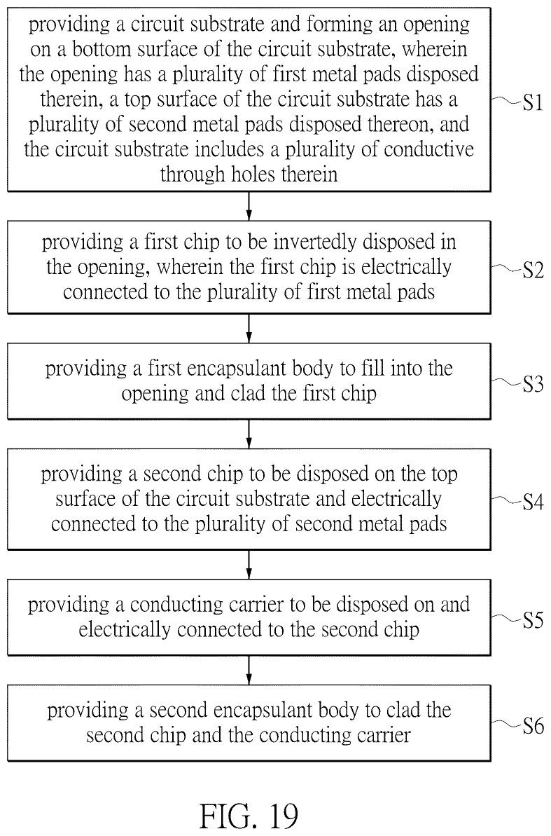

Referring to FIG. 19, the present disclosure provides a method of manufacturing the chip package structure M, which includes:
Step S1: providing a circuit substrate and forming an opening on a bottom surface of the circuit substrate, wherein the opening has a plurality of first metal pads disposed therein, a top surface of the circuit substrate has a plurality of second metal pads disposed thereon, and the circuit substrate includes a plurality of conductive through holes therein;
Step S2: providing a first chip to be invertedly disposed in the opening, wherein the first chip is electrically connected to the plurality of first metal pads;
Step S3: providing a first encapsulant body to fill into the opening and clad the first chip;
Step S4: providing a second chip to be disposed on the top surface of the circuit substrate and electrically connected to the plurality of second metal pads;
Step S5: providing a conducting carrier to be disposed on and electrically connected to the second chip; and
Step S6: providing a second encapsulant body to clad the second chip and the conducting carrier.

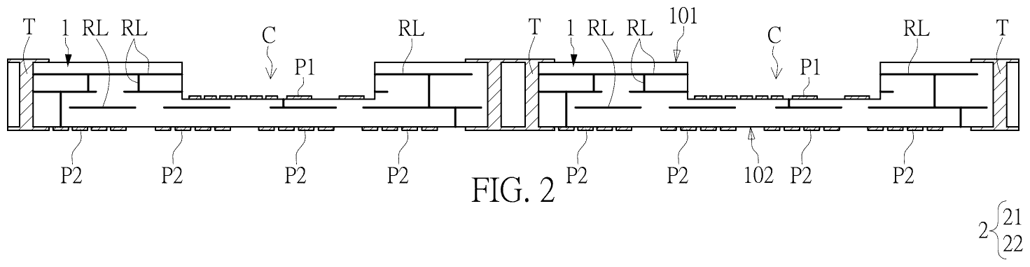

Referring to FIG. 2, in step S1, a strip-type substrate is provided, which includes a plurality of circuit substrates 1. The plurality of openings C are formed on one surface of the strip-type substrate, and the plurality of first metal pads P1 are disposed in each of the opening C. The plurality of second metal pads P2 are disposed on another surface of the strip-type substrate, and the plurality of conductive through holes T are provided inside the strip-type substrate to conduct with the two surfaces. The strip-type substrate further includes the conductive routing structure RL formed by a redistribution layer process. The plurality of first metal pads P1 and the plurality of second metal pads P2 are electrically connected to the plurality of conductive through holes T through the conductive routing structure RL. Furthermore, the strip-type substrate includes the plurality of circuit substrates 1, each of the circuit substrates 1 includes the opening C, the plurality of first metal pads P1, and the plurality of second metal pads P2.

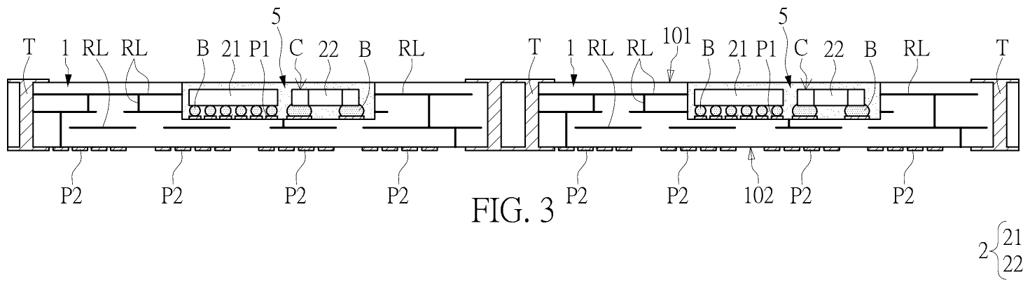

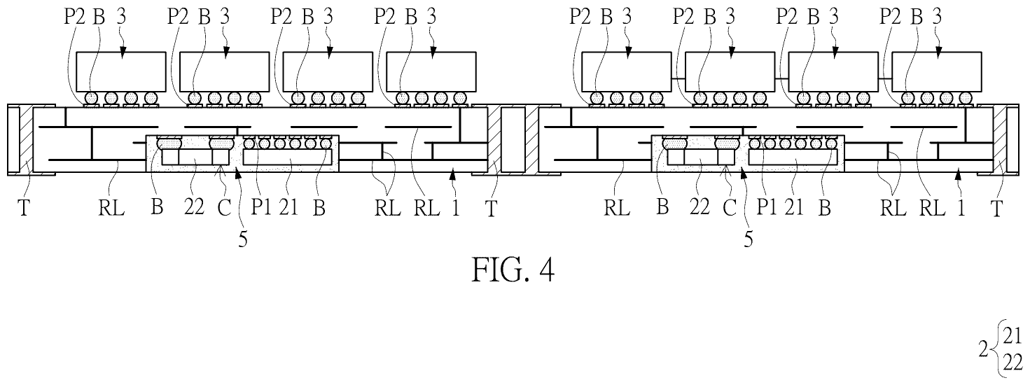

Referring to FIG. 3 and FIG. 4, in steps S2 to S4, in each of the circuit substrates 1, a plurality of first chips 2 including active element 21 and passive element 22 are disposed in the opening C in each of the circuit substrates 1. The plurality of first chips 2 are electrically connected to the plurality of first metal pads P1 through a plurality of adhesive members B such as solder or sintered silver. The first encapsulant body 5 is filled in the opening C so as to cover the plurality of first chips 2. After performing steps S2 and S3, the strip-type substrate is inverted and the openings C face downward. In other words, the surface of each of the circuit substrates 1 provided with the opening C is defined as the bottom surface 101, and another surface provided with the plurality of second metal pads P2 is defined as the top surface 102. Then, a plurality of second chips 3 are provided to be disposed on the top surface 102 of each of the circuit substrates 1, and the plurality of second chips 3 are electrically connected to the plurality of second metal pads P2 through the plurality of adhesive members B.

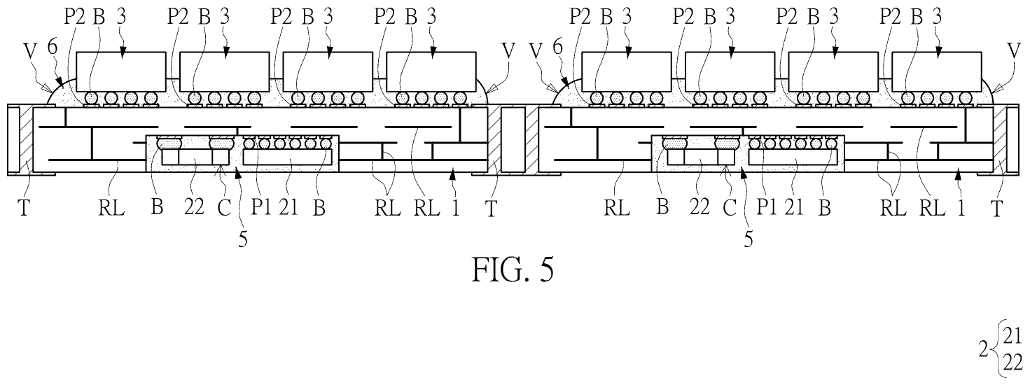

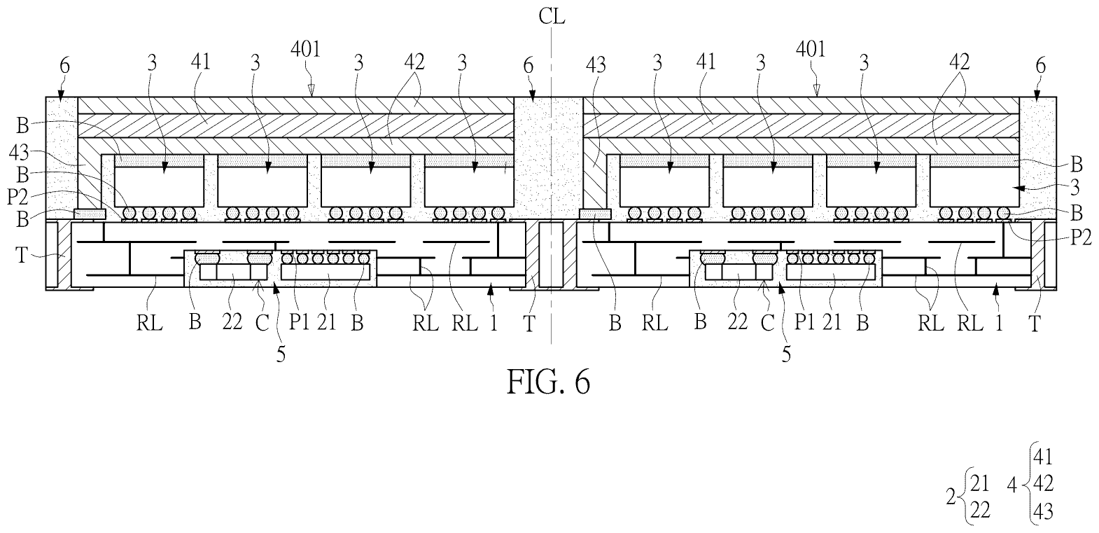

Referring to FIG. 5 and FIG. 6, in steps S5 and S6, in each of the circuit substrates 1, the conducting carrier 4 is disposed on the plurality of second chips 3. The lower surface 402 of the conducting carrier 4 is electrically connected to the plurality of second chips 3 through the plurality of adhesive members B. The metal connecting member 43 connected to the lower surface 402 of the conducting carrier 4 is electrically connected to the plurality of conductive through holes T of the circuit substrate 1. Then, the plurality of second chips 3 and the conducting carrier 4 are covered by the second encapsulant body 6, and the upper surface 401 of the conducting carrier 4 is exposed from the second encapsulant body 6.

Furthermore, the way of formation of the metal connecting member 43 is not limited in the present disclosure. Referring to FIG. 20, for example, the metal connecting member 43 can be implemented through the following steps:
Step S51: performing an etching process to form the metal connecting member on the lower surface of the conducting carrier, in which the conducting carrier is electrically connected to the plurality of conductive through holes through the metal connecting member.

More specifically, as mentioned above, in FIGS. 5 and 6, the conducting carrier 4 includes the ceramic plate 41 taken as the intermediate layer, and the two metal layers 42 that respectively cover the top side and the bottom side of the ceramic plate 41. The two metal layers 42 can be copper foil. Therefore, a part of the metal layer 42 under the ceramic plate 41 is removed through an etching process (e.g., a photolithographic etching process or a laser etching process) while leaving another part of the metal layer 42 under the ceramic plate 41. The location of the removed part forms an accommodating space to accommodate the plurality of second chips 3, and the remaining part forms the metal connecting member 43.

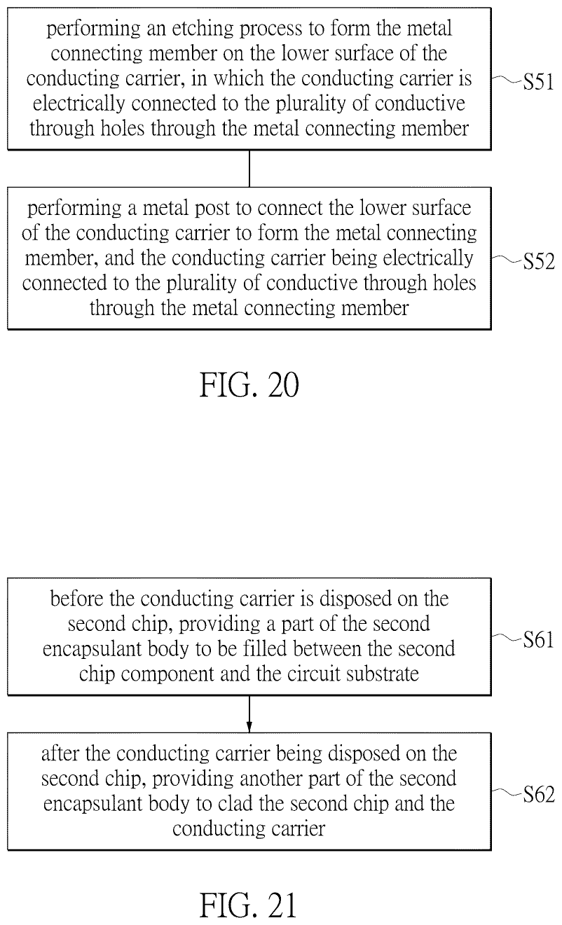

Referring to FIG. 21, the second encapsulant body 6 in step S6 can be implemented through the following steps:
Step S61: before the conducting carrier is disposed on the second chip, providing a part of the second encapsulant body to be filled between the second chip component and the circuit substrate; and
Step S62: after the conducting carrier being disposed on the second chip, providing another part of the second encapsulant body to clad the second chip and the conducting carrier.

More specifically, as shown in FIGS. 5 and 6, the second encapsulant body 6 can be formed in two stages (i.e., a first stage and a second stage). In the first stage, after the plurality of second chips 3 are connected to the corresponding circuit substrate 1 and before the corresponding conducting carrier 4 are disposed on the plurality of second chips 3, a part of the second encapsulant body 6 is filled between the plurality of second chips 3 and the circuit substrate 1. This part of the second encapsulant body 6 clads the bottom portions of the plurality of second chips 3, the plurality of second metal pads P2 on the top surface 102 of the circuit substrate 1, and the plurality of adhesive members B connected between the plurality of second chips 3 and the plurality of second metal pads P2. As shown in FIG. 5, peripheral portions on two sides of this part of the second encapsulant body 6 extend upward to side walls of the outermost two second chips 3 of the plurality of second chips 3 and form rounded contour surfaces V. In the second stage, the conducting carrier 4 is adhered on the plurality of second chips 3 through the adhesive members B, and another part of the second encapsulant body 6 is used for cladding the conducting carrier 4. Then, as shown in FIG. 6, the strip-type substrate is cut into two circuit substrates 1 along a cutting line CL to form a plurality of chip package structures M.

### Second Embodiment

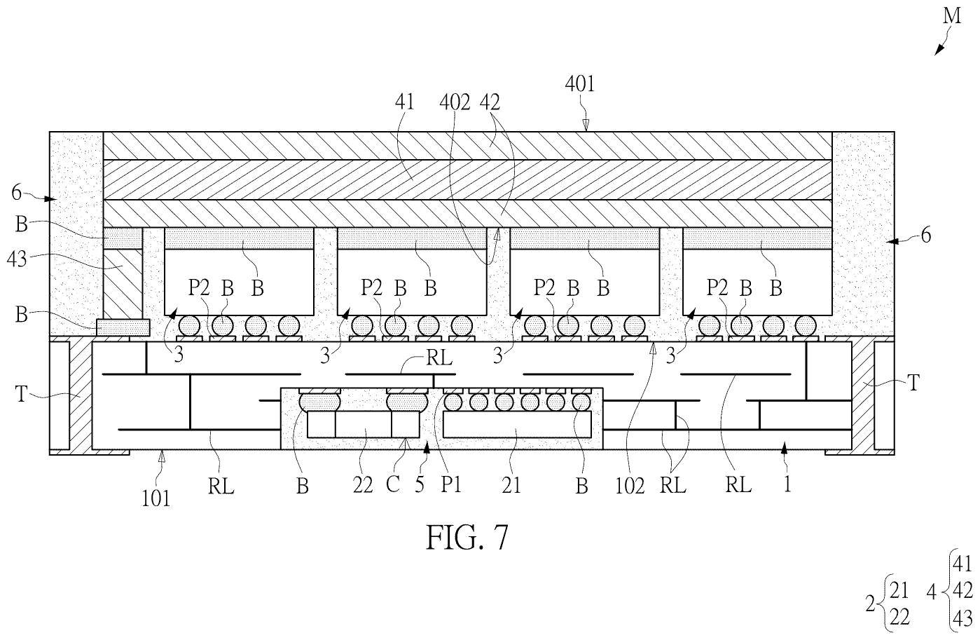

Referring to FIG. 7, FIG. 7 is a schematic view of a chip package structure according to a second embodiment of the present disclosure. The chip package structure M of the second embodiment shown in FIG. 7 has a structure similar to that of the first embodiment shown in FIG. 1, and the similarities therebetween will not be reiterated herein. The main difference between the second embodiment and the first embodiment is as follows: in the second embodiment, the metal connecting member 43 of the chip package structure M has different structures and ways of formation. Specifically, the metal connecting member 43 is an external conductor and is not part of the lower metal layer 42 of the conducting carrier 4. Two ends of the metal connecting member 43 are electrically connected to the conducting carrier 4 and one of the conductive through holes T of the circuit substrate 1 through the two adhesive members B, respectively.

As shown in FIGS. 19 and 20, for example, the metal connecting member 43 can further be implemented through the following steps:
Step S52: performing a metal post to connect the lower surface of the conducting carrier to form the metal connecting member, and the conducting carrier being electrically connected to the plurality of conductive through holes through the metal connecting member.

More specifically, the metal connecting member 43 can be a metal post (e.g., a copper pillar), which is formed by connecting to the lower surface 402 of the conducting carrier 4 through an adhesive member B such as solder or sintered silver. The metal post can elevate the conducting carrier 4, such that an accommodation space is formed between the conducting carrier 4 and the circuit substrate 1 to accommodate the plurality of second chips 3.

### Third Embodiment

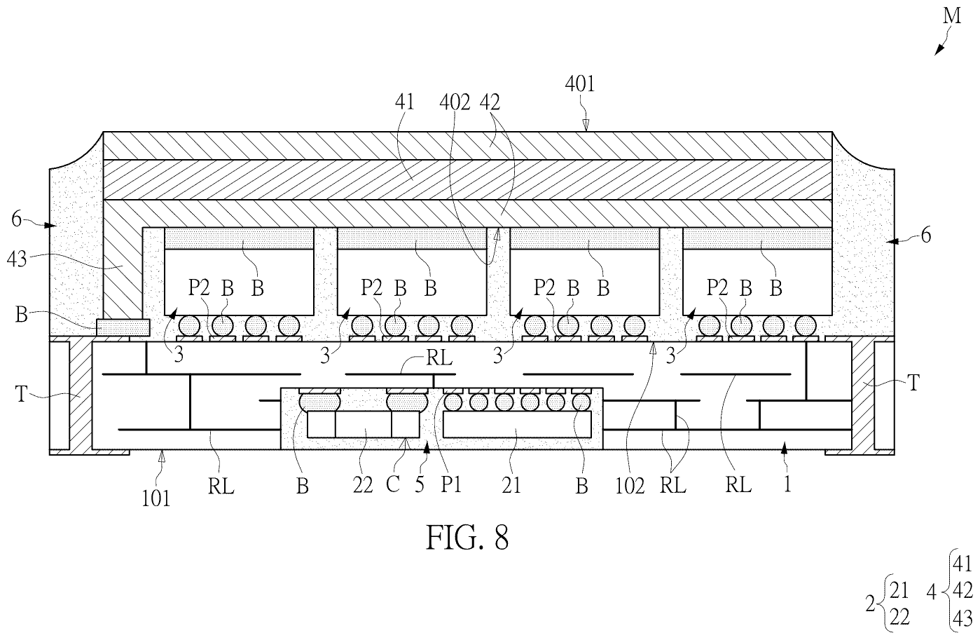

Referring to FIG. 8, FIG. 8 is a schematic view of a chip package structure according to a third embodiment of the present disclosure. The chip package structure M of the third embodiment shown in FIG. 8 has a structure similar to that of the first embodiment shown in FIG. 1, and the similarities therebetween will not be reiterated herein. The main difference between the third embodiment and the first embodiment is as follows: in the third embodiment, the first encapsulant body 5 and the second encapsulant body 6 of the chip package structure M can be liquid encapsulants. Therefore, upper edges of two sides of the second encapsulant body 6 form concave shapes.

### Fourth Embodiment

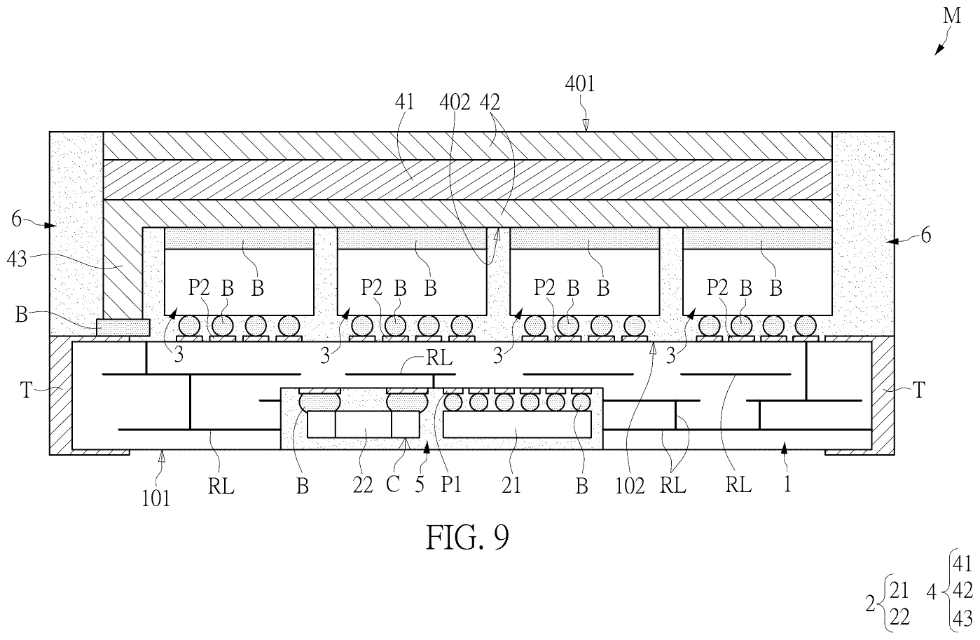

Referring to FIG. 9, FIG. 9 is a schematic view of a chip package structure according to a fourth embodiment of the present disclosure. The chip package structure M of the fourth embodiment shown in FIG. 9 has a structure similar to that of the first embodiment shown in FIG. 1, and the similarities therebetween will not be reiterated herein. The main difference between the fourth embodiment and the first embodiment is as follows: in the fourth embodiment, the conductive through holes T are formed on two sides or three sides or four sides (depending on the pin count number and layout feasibility) of outer surface of the circuit substrate 1, such that each of the conductive through holes T is a semi-cylindrical through hole exposed on the two sides of the outer surface of the circuit substrate 1, to form a castellation structure. Therefore, when the chip package structure M is soldered to the mainboard through solder, the solder extends upward along the castellation structure (i.e., the semi-cylindrical conductive through holes T) to strengthen the bonding strength between the chip package structure M and the mainboard.

### Fifth Embodiment

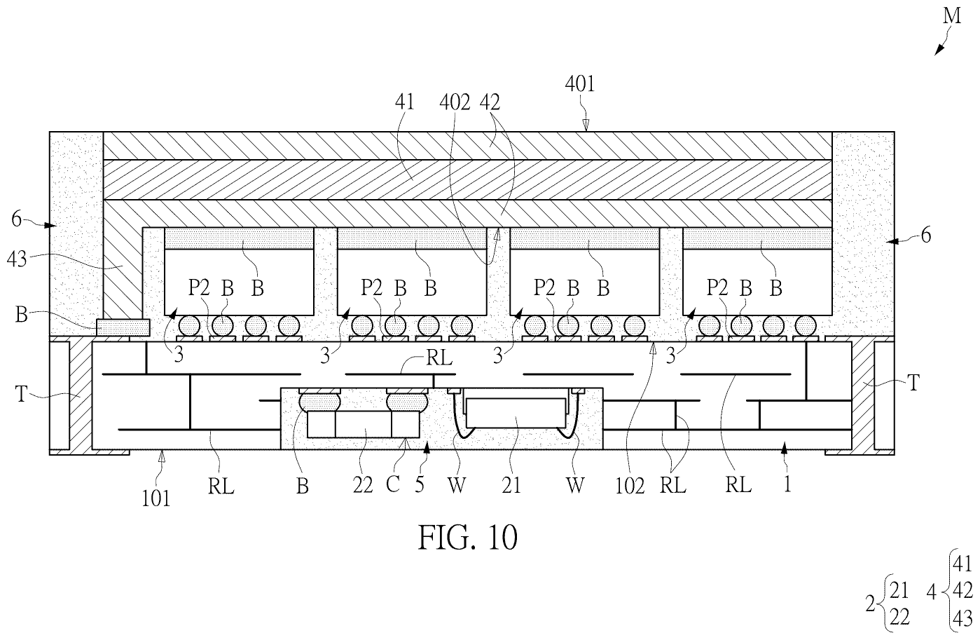

Referring to FIG. 10, FIG. 10 is a schematic view of a chip package structure according to a fifth embodiment of the present disclosure. The chip package structure M of the fifth embodiment shown in FIG. 10 has a structure similar to that of the first embodiment shown in FIG. 1, and the similarities therebetween will not be reiterated herein. The main difference between the fifth embodiment and the first embodiment is as follows: in the fifth embodiment, the first chip 2, such as the active element 21 in FIG. 10, is electrically connected to the plurality of first metal pads P1 through metal wires W.

### Sixth Embodiment

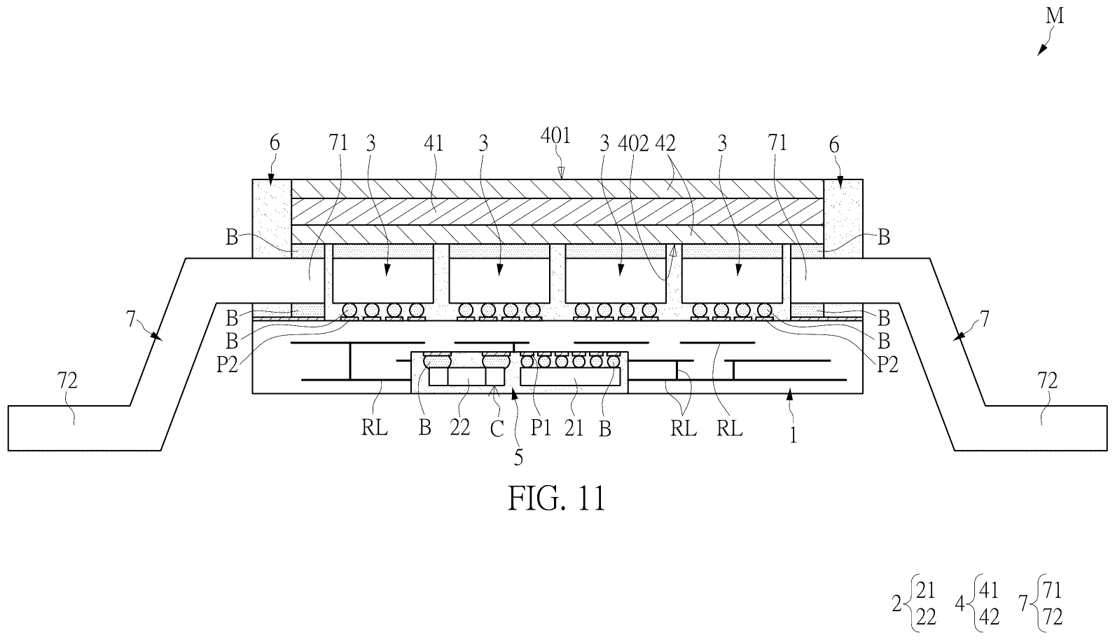

Referring to FIG. 11, FIG. 11 is a schematic view of a chip package structure according to a sixth embodiment of the present disclosure. The chip package structure M of the sixth embodiment shown in FIG. 11 has a structure similar to that of the first embodiment shown in FIG. 1, and the similarities therebetween will not be reiterated herein. The main difference between the sixth embodiment and the first embodiment is as follows: in the sixth embodiment, the chip package structure M further includes two lead frames 7, which are respectively located at two sides of the plurality of second chips 3 and are electrically connected to the conducting carrier 4 and the circuit substrate 1. Moreover, in the sixth embodiment, the circuit substrate 1 does not include the conductive through holes, and the conducting carrier 4 does not include the metal connecting member.

Furthermore, each of the lead frames 7 has a first end 71 and a second end 72. The first end 71 is electrically connected to the conducting carrier 4 and one of the second metal pads P2 on the circuit substrate 1 through adhesive members B. The second end 72 is arranged horizontally and is soldered to the mainboard through solder. In other embodiments, the second end 72 of the lead frames 7 can be directly and vertically plugged into the mainboard. Therefore, the first chip 2 and the second chips 3 are electrically connected to other electronic components on the mainboard through the lead frames 7.

### Seventh Embodiment

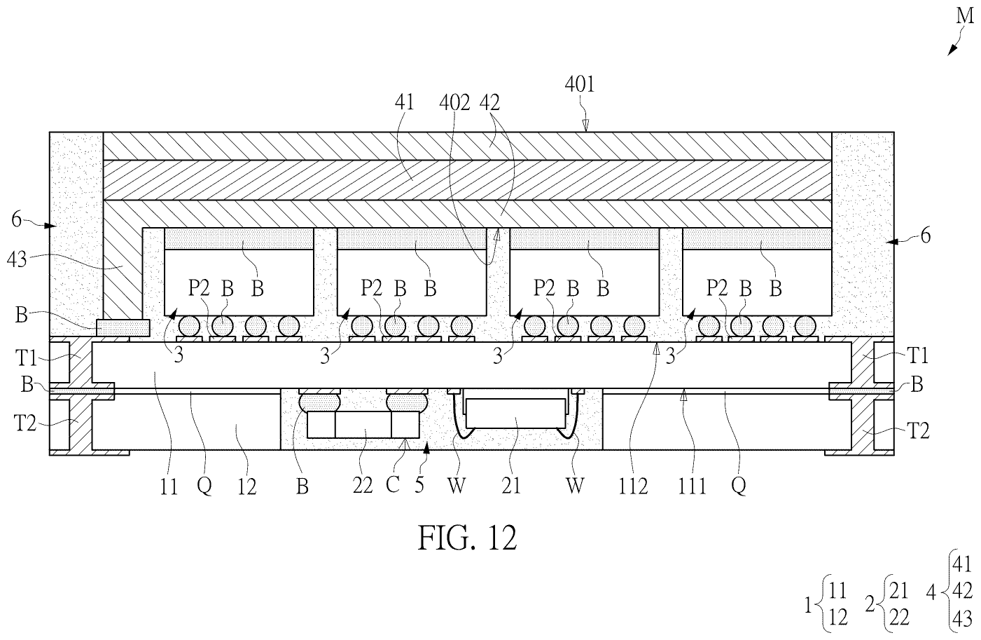

Referring to FIG. 12, FIG. 12 is a schematic view of a chip package structure according to a seventh embodiment of the present disclosure. The chip package structure M of the seventh embodiment shown in FIG. 12 has a structure similar to that of the first embodiment shown in FIG. 1, and the similarities therebetween will not be reiterated herein. The main difference between the seventh embodiment and the first embodiment is as follows: in the seventh embodiment, the circuit substrate 1 is a double-layer plate structure. More specifically, the circuit substrate 1 includes a first structural layer 11 and a second structural layer 12 that are stacked up and down. The first structural layer 11 and the second structural layer 12 are bonded to each other by an adhesion material Q. For example, each of the first structural layer 11 and the second structural layer 12 is a DPC substrate, which includes an intermediate layer, an upper layer, and a lower layer. The intermediate layer is a ceramic plate, and the upper and lower layers are copper foil. The adhesion material Q is thermal interface material or Ajinomoto Build-Up Film® (ABF). Since both of the first structural layer 11 and the second structural layer 12 are ceramic substrates directly plated copper, the conductive performance of the circuit substrate 1 can be further enhanced by arranging multiple thick layers of copper foil.

Further, the first structural layer 11 has a first surface 111 and a second surface 112 that are opposite to each other, and the first structural layer 11 includes a plurality of first conductive through holes T1 to conduct the first surface 111 and the second surface 112. Similarly, the second structural layer 12 includes a plurality of second conductive through holes T2 to conduct upper and lower surfaces of the second structural layer 12. When the first structural layer 11 is stacked on the second structural layer 12, the second structural layer 12 covers the first surface 111, the plurality of first conductive through holes T1 respectively correspond to the plurality of second conductive through holes T2, and the plurality of first conductive through holes T1 and the plurality of second conductive through holes T2 are electrically connected to each other through the plurality of adhesive members B (such as solder or sintered silver), such that the conducting carrier 4 are electrically connected to one of the first conductive through holes T1 through the metal connector 43.

A middle part of the second structural layer 12 is removed for forming the opening C to expose a part of the first surface 111. In addition, the first surface 111 and the second surface 112 of the first structural layer 11 both have routing layers (i.e., the conductive routing structure, not shown in the figures) to electrically connect the plurality of first conductive through holes T1 and the plurality of second conductive through holes T2. The exposed part of the first surface 111 includes a plurality of first metal pads P1 that are electrically connected to the routing layers, and the second surface 112 includes a plurality of second metal pads P2 that are electrically connected to the routing layers. The surface of the second structural layer 12 is not provided with a circuit layer and only has the conductive through holes formed thereon.

The first chip 2 (i.e., the active element 21 and the passive element 22) is disposed within the opening C and is electrically connected to the plurality of first metal pads P1 through adhesive members B or metal wires W. The second chips 3 are disposed on the second surface 112 and are electrically connected to the plurality of second metal pads P2. Therefore, the first chip 2 and the second chips 3 are electrically connected to the plurality of first conductive through holes T1 and second conductive through holes T2 through the first metal pads P1 and the second metal pads P2, respectively.

### Eighth Embodiment

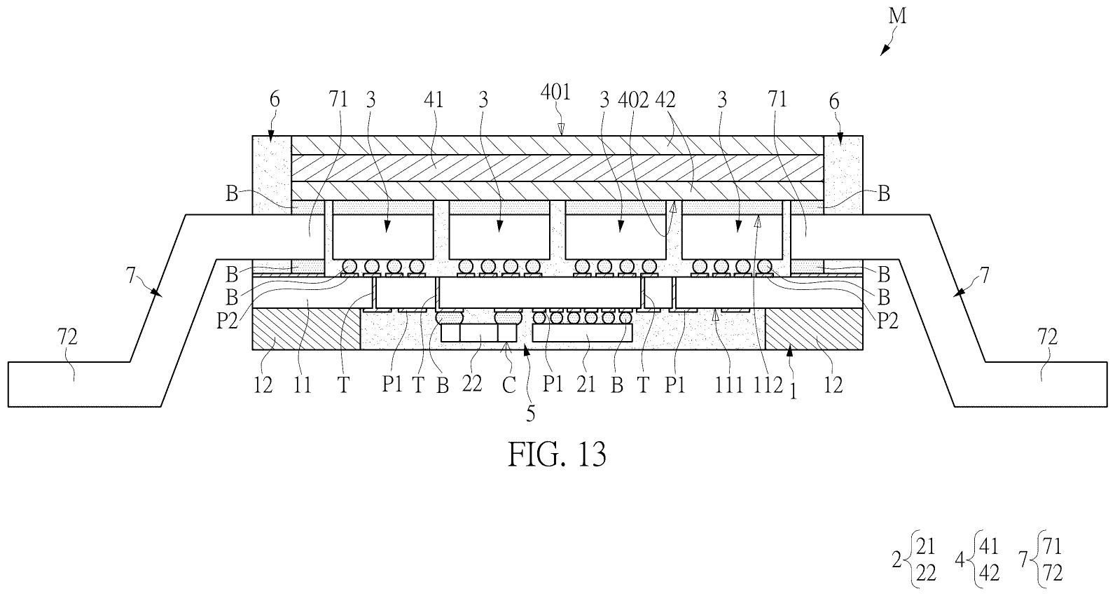

Referring to FIG. 13, FIG. 13 is a schematic view of a chip package structure according to an eighth embodiment of the present disclosure. The chip package structure M of the eighth embodiment shown in FIG. 13 has a structure similar to that of the seventh embodiment shown in FIG. 12, and the similarities therebetween will not be reiterated herein. The main difference between the eighth embodiment and the seventh embodiment is as follows: in the eighth embodiment, the circuit substrate 1 is an AMB substrate or a DBC substrate with only a single metal layer, so that the size of the chip package structure M can be reduced.

The circuit substrate 1 includes a first structural layer 11 and a second structural layer 12. The first structural layer 11 is a ceramic plate, and the second structural layer 12 is a metal layer, such as copper foil. The first structural layer 11 has a first surface 111 and a second surface 112, and the second structural layer 12 covers the first surface 111. A middle part of the second structural layer 12 is removed for forming the opening C to expose a part of the first surface 111. The exposed part of the first surface 111 includes a plurality of first metal pads P1, and the second surface 112 includes a plurality of second metal pads P2. A plurality of conductive through holes T are formed inside the first structural layer 11 to electrically connect the plurality of first metal pads P1 and the plurality of second metal pads P2. The first chip 2 is disposed in the opening C and is electrically connected to the plurality of first metal pads P1 through adhesive members B or metal wires, and the plurality of second chips 3 are disposed on the second surface 112 of the first structural layer 11 and are electrically connected to the plurality of second metal pads P2.

The chip package structure M further includes two lead frames 7, which are respectively located at two sides of the plurality of second chips 3 and are electrically connected to the conducting carrier 4 and the circuit substrate 1. Each of the lead frames 7 has a first end 71 and a second end 72. The first end 71 is electrically connected to the conducting carrier 4 and one of the second metal pads P2 on the circuit substrate 1 through adhesive members B. The second end 72 is arranged horizontally and is soldered to the mainboard through solder. Therefore, the first chip 2 and the second chips 3 are electrically connected to other electronic components on the mainboard through the lead frames 7.

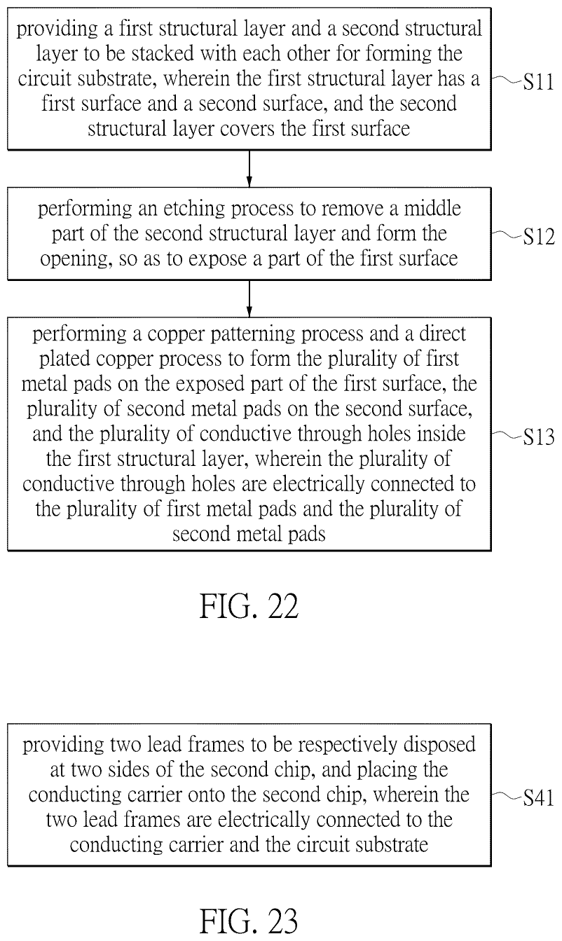

As shown in FIG. 19, the manufacturing method of the chip package structure provided by the present disclosure can be used to manufacture the chip package structure M of the eighth embodiment. Steps S1 to S6 have been described in detail in the first embodiment and will not be reiterated herein. Referring to FIG. 22, the circuit substrate 1 in step S1 can be further implemented through the following steps:
Step S11: providing a first structural layer and a second structural layer to be stacked with each other for forming the circuit substrate, wherein the first structural layer has a first surface and a second surface, and the second structural layer covers the first surface;
Step S12: performing an etching process to remove a middle part of the second structural layer and form the opening, so as to expose a part of the first surface; and
Step S13: performing a copper patterning process and a direct plated copper process to form the plurality of first metal pads on the exposed part of the first surface, the plurality of second metal pads on the second surface, and the plurality of conductive through holes inside the first structural layer, wherein the plurality of conductive through holes are electrically connected to the plurality of first metal pads and the plurality of second metal pads.

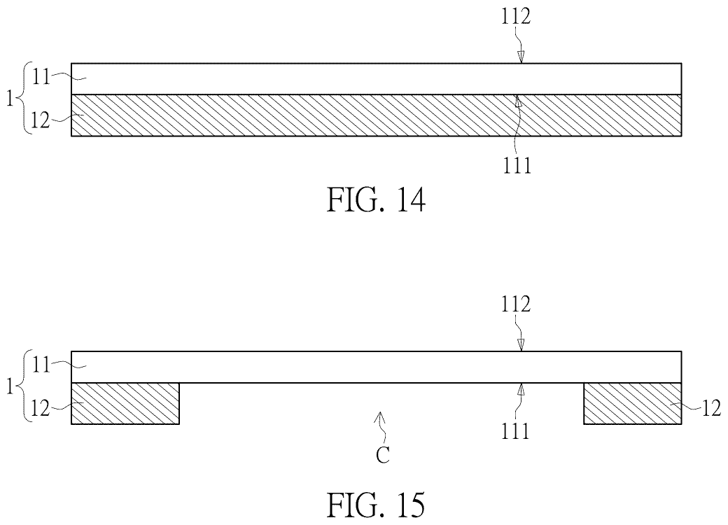

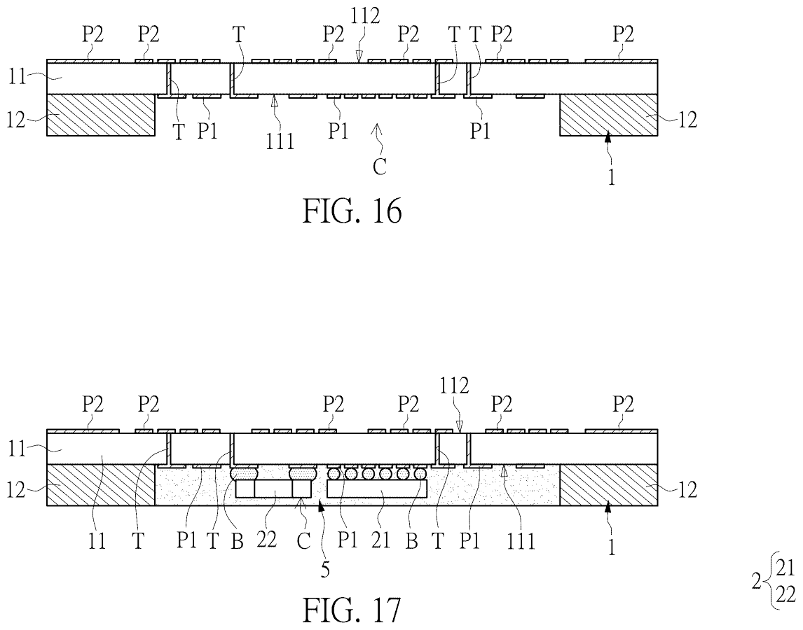

Referring to FIG. 14 to FIG. 18, FIG. 14 to FIG. 18 are schematic views of steps of a manufacturing method of the chip package structure according to the eighth embodiment of the present disclosure. Specifically, as shown in FIG. 14 to FIG. 16, a ceramic plate is provided as the first structural layer 11, and a layer of copper foil is provided to cover on the first surface 111 of the first structural layer 11 as the second structural layer 12. The opening C is formed by removing the middle part of the second structural layer 12 through an etching process (e.g., a photolithographic etching process or a laser etching process), and a portion of the first surface 111 is exposed from the opening C. The plurality of first metal pads P1 are formed on the exposed portion of the first surface 111 through a copper patterning process such as a DPC process, and the plurality of second metal pads P2 are formed on the second surface 112 of the first structural layer 11. The plurality of conductive through holes T are formed inside the first structural layer 11 through a direct copper plating (DPC) process in which a laser drilling process is applied to make the holes and a copper plating process is followed to form conductors inside the holes, and the plurality of conductive through holes T are electrically connected to the plurality of first metal pads P1 and the plurality of second metal pads P2.

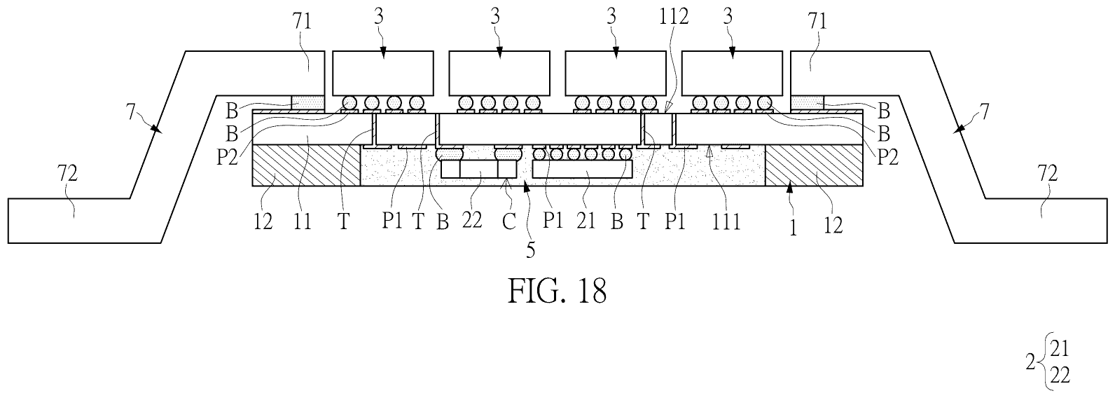

As shown in FIG. 17, the first chip 2 (i.e., the active element 21 and the passive element 22) is invertedly disposed within the opening C. The first chip 2 is electrically connected to the plurality of first metal pads P1, and the first encapsulant body 5 is filled in the opening C to cover the first chip 2. As shown in FIG. 18, the second chips 3 are disposed on the second surface 112 of the first structural layer 11 and is electrically connected to the plurality of second metal pads P2.

Referring to FIG. 23, after performing step S4, the manufacturing method of the chip package structure M of the eighth embodiment further includes the following steps:
Step S41: providing two lead frames to be respectively disposed at two sides of the second chip, and placing the conducting carrier onto the second chip, wherein the two lead frames are electrically connected to the conducting carrier and the circuit substrate.

Specifically, as shown in FIG. 18 and FIG. 13, in step S41, the two lead frames 7 are respectively disposed at two sides of the plurality of second chips 3 and are electrically connected to the conducting carrier 4 and the circuit substrate 1 through the adhesive members B, such that the first chip 2 and the plurality of second chips 3 are electrically connected to other electronic components on the mainboard through the lead frames 7. The conducting carrier 4 (including the ceramic plate 41 as an intermediate layer, and the two metal layers 42 respectively covering the upper and lower sides of the ceramic plate 41) is disposed on the plurality of second chips 3 and is electrically connected to the plurality of second chips 3. Then, the second encapsulant body 6 clads the plurality of second chips 3, a part of the lead frames 7 (the first ends 71 of the lead frames 7), and the conducting carrier 4, and exposes the upper surface 401 of the conducting carrier 4, thereby completing the formation of the chip package structure M of the eighth embodiment.

### Beneficial Effects of the Embodiments

In the chip package structure M and the manufacturing method thereof provided by the present disclosure, by virtue of the first chip 2 being disposed within the opening C and electrically connected to the circuit substrate 1, and the second chips 3 being disposed on the top surface 102 of the circuit substrate 1 and electrically connected to the circuit substrate 1 through the conducting carrier 4 and the metal connecting member 43, different electronic components can be integrated onto a substrate to form a system in package structure. When the chip package structure M is soldered to the mainboard, the layout complexity of the circuit routing can be greatly reduced, which is beneficial for reducing the overall size of the power modules, and declining the development time and manufacturing cost of the power modules.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip package structure, comprising:
a circuit substrate including a plurality of conductive through holes, wherein a bottom surface of the circuit substrate has an opening;
a first chip disposed within the opening and being electrically connected to the circuit substrate;
a second chip disposed on a top surface of the circuit substrate; and
a conducting carrier disposed on the second chip and electrically connected to the second chip.

2. The chip package structure according to claim 1, wherein the circuit substrate is a ceramic substrate made of low temperature co-fired ceramics.

3. The chip package structure according to claim 1, wherein the conducting carrier is a direct bonded copper substrate, a direct plated copper substrate or an active metal brazing substrate.

4. The chip package structure according to claim 1, further comprising a first encapsulant body filled into the opening and cladding the first chip.

5. The chip package structure according to claim 4, further comprising a second encapsulant body disposed on the circuit substrate and cladding the conducting carrier and the second chip, wherein the conducting carrier further has an upper surface, and the upper surface is exposed from the second encapsulant body.

6. The chip package structure according to claim 5, wherein each of the first encapsulant body and the second encapsulant body is a liquid encapsulant or a molding compound.

7. The chip package structure according to claim 1, wherein the conducting carrier includes a metal connecting member connected to a lower surface of the conducting carrier and located at one side of the second chip, and the conducting carrier is electrically connected to one of the conductive through holes through the metal connecting member.

8. The chip package structure according to claim 7, wherein the metal connecting member is a copper foil or a copper pillar.

9. The chip package structure according to claim 7, wherein the plurality of conductive through holes are formed inside the circuit substrate, and the plurality of conductive through holes pass through the circuit substrate and are exposed from the bottom surface and the top surface.

10. The chip package structure according to claim 9, wherein the plurality of conductive through holes are formed on outer surfaces of both sides of the circuit substrate, and extend to the bottom surface and the top surface.

11. The chip package structure according to claim 1, wherein the circuit substrate includes a conductive routing structure formed therein by a redistribution layer process; wherein the opening has a plurality of first metal pads disposed therein, the top surface of the circuit substrate has a plurality of second metal pads disposed thereon, the plurality of first metal pads and the plurality of second metal pads are electrically connected to the conductive through holes through the conductive routing structure, the first chip is electrically connected to the plurality of first metal pads, and the second chip is electrically connected to the plurality of second metal pads.

12. The chip package structure according to claim 1, wherein the circuit substrate includes a first structural layer and a second structural layer, the first structural layer and the second structural layer are bonded to each other by an adhesion material, the first structural layer includes a plurality of first conductive through holes, the second structural layer includes a plurality of second conductive through holes, and the plurality of first conductive through holes are electrically connected to the plurality of second conductive through holes through a plurality of adhesive members.

13. The chip package structure according to claim 12, wherein the first structural layer has a first surface and a second surface, the second structural layer covers the first surface, and the opening is formed on the second structural layer to expose a part of the first surface; wherein the exposed part of the first surface includes a plurality of first metal pads, the second surface includes a plurality of second metal pads, the first chip is disposed in the opening and electrically connected to the plurality of first metal pads, and the second chip is disposed on the second surface and electrically connected to the plurality of second metal pads.

14. The chip package structure according to claim 13, wherein the first structural layer and the second structural layer are direct plated copper ceramic substrates, and the adhesion material is a thermal interface material or a low dielectric material.

15. The chip package structure according to claim 1, wherein the first chip includes at least one passive element, at least one control semiconductor chip or at least one drive semiconductor chip, and the first chip is connected to the conducting carrier through an adhesive member.

16. The chip package structure according to claim 1, wherein the second chip includes at least one power semiconductor chip, and the second chip is connected to the circuit substrate through an adhesive member; wherein the at least one power semiconductor chip is a metal-oxide-semiconductor field-effect transistor or an insulated gate bipolar transistor.

17. The chip package structure according to claim 1, wherein the second chip includes a power semiconductor chip, and the second chip is electrically connected to the circuit substrate through at least one metal conductive wire.

18. The chip package structure according to claim 1, further comprising two lead frames respectively located at two sides of the second chip, wherein the lead frames are electrically connected to the conducting carrier and the circuit substrate.

19. The chip package structure according to claim 1, wherein the circuit substrate includes a first structural layer and a second structural layer that are stacked one on top of another, the first structural layer has a first surface and a second surface, the second structural layer covers the first surface, and the opening is formed on the second structural layer to expose a part of the first surface; wherein the exposed part of the first surface includes a plurality of first metal pads, the second surface includes a plurality of second metal pads, and the plurality of conductive through holes are formed inside the first structural layer to be electrically connected to the plurality of first metal pads and the plurality of second metal pads.

20. The chip package structure according to claim 19, wherein the first chip is disposed in the opening and electrically connected to the plurality of first metal pads, and the second chip is disposed on the second surface and electrically connected to the plurality of second metal pads.

21. The chip package structure according to claim 19, wherein the first structural layer is a ceramic plate, and the second structural layer is a metal layer.

22. A method of manufacturing a chip package structure, comprising:
providing a circuit substrate and forming an opening on a bottom surface of the circuit substrate, wherein the opening has a plurality of first metal pads disposed therein, a top surface of the circuit substrate has a plurality of second metal pads disposed thereon, and the circuit substrate includes a plurality of conductive through holes therein;
providing a first chip to be invertedly disposed in the opening, wherein the first chip is electrically connected to the plurality of first metal pads;
providing a first encapsulant body to be filled into the opening and clad the first chip;
providing a second chip to be disposed on the top surface of the circuit substrate and electrically connected to the plurality of second metal pads;
providing a conducting carrier to be disposed on and electrically connected to the second chip; and
providing a second encapsulant body to clad the second chip and the conducting carrier.

23. The method of manufacturing a chip package structure according to claim 22, wherein the circuit substrate includes a conductive routing structure formed therein by a redistribution layer process, and the plurality of first metal pads and the plurality of second metal pads are electrically connected to the plurality of conductive through holes through the conductive routing structure.

24. The method of manufacturing a chip package structure according to claim 22, wherein the conducting carrier includes a metal connecting member connected to a lower surface of the conducting carrier and located at one side of the second chip, and the conducting carrier is electrically connected to the plurality of conductive through holes through the metal connecting member.

25. The method of manufacturing a chip package structure according to claim 24, wherein the step of providing the conducting carrier to be disposed on and electrically connected to the second chip further includes:
performing an etching process to form the metal connecting member on the lower surface of the conducting carrier, the conducting carrier being electrically connected to the plurality of conductive through holes through the metal connecting member.

26. The method of manufacturing a chip package structure according to claim 24, wherein the step of providing the conducting carrier to be disposed on and electrically connected to the second chip further includes:
performing a metal post to connect the lower surface of the conducting carrier to form the metal connecting member, the conducting carrier being electrically connected to the plurality of conductive through holes through the metal connecting member.

27. The method of manufacturing a chip package structure according to claim 22, wherein the step of providing the second encapsulant body to clad the second chip and the conducting carrier further includes:
before the conducting carrier is disposed on the second chip, providing a part of the second encapsulant body to be filled between the second chip component and the circuit substrate; and
after the conducting carrier is disposed on the second chip, providing another part of the second encapsulant body to clad the second chip and the conducting carrier.

28. The method of manufacturing a chip package structure according to claim 22, wherein the circuit substrate is a ceramic substrate made of low temperature co-fired ceramics.

29. The method of manufacturing a chip package structure according to claim 22, wherein the conducting carrier is a direct bonded copper substrate, a direct plated copper substrate or an active metal brazing substrate.

30. The method of manufacturing a chip package structure according to claim 22, wherein each of the first encapsulant body and the second encapsulant body is a liquid encapsulant or a molding compound.

31. The method of manufacturing a chip package structure according to claim 22, wherein the step of providing the circuit substrate and forming the opening on the bottom surface thereof further includes:
providing a first structural layer and a second structural layer to be stacked with each other for forming the circuit substrate, wherein the first structural layer has a first surface and a second surface, and the second structural layer covers the first surface;
performing an etching process to remove a middle part of the second structural layer and form the opening, so as to expose a part of the first surface; and
performing a copper patterning process and a direct plated copper process to form the plurality of first metal pads on the exposed part of the first surface, the plurality of second metal pads on the second surface, and the plurality of conductive through holes inside the first structural layer, wherein the plurality of conductive through holes are electrically connected to the plurality of first metal pads and the plurality of second metal pads.

32. The method of manufacturing a chip package structure according to claim 31, wherein, after providing the second chip to be disposed on the top surface of the circuit substrate and electrically connected to the plurality of second metal pads, the method further includes:
providing two lead frames to be respectively disposed at two sides of the second chip, and placing the conducting carrier onto the second chip, wherein the two lead frames are electrically connected to the conducting carrier and the circuit substrate.
